(19) United States
(12) Patent Application Publication
(10) Pub. No.: US 2025/0199105 A1
(43) Pub. Date: Jun. 19, 2025

(54) PROCESSING DEVICE AND OUTPUT DEVICE

(71) Applicant: Osaka University, Osaka (JP)

(72) Inventors: Shuichi TSURUTA, Osaka (JP); Toshikazu NEZU, Osaka (JP); Hiroshi OHTA, Osaka (JP)

(21) Appl. No.: 18/848,887

(22) PCT Filed: Mar. 17, 2023
(86) PCT No.: PCT/JP2023/010701

§ 371 Date: Sep. 19, 2024

(30) Foreign Application Priority Data
Mar. 24, 2022 (JP) 2022-047990

(51) Int. Cl. G01R 35/00; H03M 1/10

(52) U.S. Cl. CPC G01R 35/005; H03M 1/1014

(57) ABSTRACT

A processing device is built into an output device, which uses a DA converter to output a predetermined voltage value serving as a reference. The processing device includes an input voltage acquisition unit, which acquires a positive reference voltage value and a negative reference voltage value output as internal reference voltage values from an internal voltage supply in the output device. An output voltage acquisition unit acquires a positive output voltage value and a negative output voltage value output from the DA converter. An adjustment unit adjusts a set value of the DA converter and adjusts the acquired positive output voltage value and negative output voltage value toward the acquired positive reference voltage value and negative reference voltage value.

### TECHNICAL FIELD

The present invention relates to a processing device and an output device.

### BACKGROUND ART

Japan is ahead of the rest of the world in terms of declining birthrates, aging population, and decrease in population, and is a developed country facing these challenges. Problems related to the maintenance of public services, such as healthcare infrastructure, are just beginning to come to the surface. There is a need to solve these problems using advanced sensors. For example, it has been recently required to accurately measure signals that are several orders of magnitude smaller than normal signals: sensors having accuracy in a microvolt region instead of a millivolt region are required in order to tackle social challenges such as disease tests, nondestructive inspection, etc. As a device for performing measurement with such accuracy, for example, a measurement circuit for measuring power supply noise generated in a semiconductor device has been proposed, for example (see Patent Document 1).
Patent Document 1: Japanese Unexamined Patent Application, Publication No. 2015-135284

### DISCLOSURE OF THE INVENTION

### Problems to be Solved by the Invention

Here, equipment for which accuracy is required, such as the device disclosed in Patent Document 1, experiences changes in its performance capability and electrical characteristics due to age-related deterioration and use conditions. Since such changes can lead to a measurement error or a malfunction, it is necessary to ensure the reliability of the equipment as appropriate.

On the other hand, in order to ensure the reliability of equipment with higher accuracy, it is necessary to calibrate, with reference to a primary standard, target equipment to be adjusted so as to adjust a deviation. In addition, it is favorable to improve the accuracy of the target equipment by adjusting an error inherent in the target equipment.

The present invention has been achieved in view of the circumstances described above, and is intended to provide a processing device and an output device that are capable of improving accuracy by adjusting an error inherent in equipment.

### Means for Solving the Problems

The present invention relates to a processing device incorporatable in an output device that outputs, by using a DA converter, a predetermined voltage value serving as a reference. The processing device includes: an input voltage acquisition unit configured to acquire a positive reference voltage value and a negative reference voltage value outputted as internal reference voltage values from an internal voltage supply that is provided in the output device; an output voltage acquisition unit configured to acquire a positive output voltage value and a negative output voltage value outputted from the DA converter; and an adjustment unit configured to adjust a setting value of the DA converter and adjust the positive output voltage value and the negative output voltage value toward the positive reference voltage value acquired and the negative reference voltage value acquired.

Preferably, the processing device further includes a notification unit configured to notify an adjustment result of adjustment by the adjustment unit to an outside. The input voltage acquisition unit preferably acquires a positive voltage value of interest and a negative voltage value of interest that are outputted from target equipment to be adjusted and are assumed to be equal to the internal reference voltage values, and the adjustment unit preferably adjusts the positive output voltage value and the negative output voltage value toward the positive voltage value of interest acquired and the negative voltage value of interest acquired.

The processing device may further include a conversion unit configured to perform conversion of an adjustment result to a measurement value of a voltage value of interest outputted from the target equipment, and the notification unit may notify the measurement value resulting from the conversion.

The processing device may further include a conversion unit configured to perform conversion of an adjustment result to a calibration value for calibrating a voltage value of interest outputted from the target equipment, and the notification unit may notify the calibration value resulting from the conversion.

The processing device may further include a temperature acquisition unit configured to acquire a temperature of an ambient atmosphere, and the adjustment unit may adjust a setting value of the DA converter based on the positive reference voltage value, the negative reference voltage value, and the temperature acquired.

The input voltage acquisition unit may acquire a reference calibration voltage value for calibrating the internal reference voltage values, the reference calibration voltage value being provided from an outside of the output device, and the adjustment unit may adjust the positive output voltage value and the negative output voltage value toward the reference calibration voltage value by adjusting a setting value of the DA converter.

The adjustment unit may change an adjustment result based on a voltage value preset as an output value of the DA converter.

Furthermore, the present invention relates to an output device includes: the processing device described above; the internal voltage supply; an inverting circuit that inverts positive and negative of the internal voltage supply; an input terminal that is used to receive an input of a voltage value from an outside; an output terminal that is used to output a voltage value to the outside; and a DA converter that outputs a predetermined voltage value to the output terminal and is adjustable with an adjustment value that is determined based on adjustment by the adjustment unit.

Moreover, the present invention relates to a program for causing a computer to operate as a processing device incorporatable in an output device that outputs, by using a DA converter, a predetermined voltage value serving as a reference. The program causes the computer to function as units including: an input voltage acquisition unit configured to acquire a positive reference voltage value and a negative reference voltage value outputted as internal reference voltage values from an internal voltage supply that is provided in the output device; an output voltage acquisition unit configured to acquire a positive output voltage value and a negative output voltage value outputted from the DA converter; and an adjustment unit configured to adjust a setting value of the DA converter and adjust the positive output voltage value and the negative output voltage value toward the positive reference voltage value acquired and the negative reference voltage value acquired.

### Effects of the Invention

The present invention can provide a processing device and an output device that are capable of improving accuracy by adjusting an error inherent in equipment.

### BRIEF DESCRIPTION OF THE DRAWINGS

FIG. 1 is a schematic diagram illustrating a connection of an output device according to an embodiment of the present invention;

FIG. 2 is a block diagram illustrating a configuration of an output device according to a first embodiment;

FIG. 3 is a block diagram illustrating a configuration of an output device according to a second embodiment of the present invention;

FIG. 4 is a schematic diagram illustrating a connection of an output device according to a third embodiment of the present invention; and

FIG. 5 is a block diagram illustrating a configuration of the output device according to the third embodiment.

### PREFERRED MODE FOR CARRYING OUT THE INVENTION

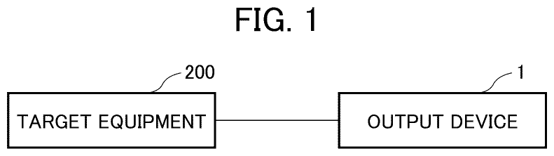

An output device 1 and a processing device 100 according to each embodiment of the present invention will be described with reference to FIGS. 1 to 5. First, the outline of the output device 1 will be described. In the following embodiments, the term “calibration” refers to identifying a deviation (error) of a value of a signal outputted from equipment, with respect to a reference value. The term “adjustment” refers to adjusting an output signal of equipment (e.g., target equipment 200 to be described below) to a reference value by way of elimination of a deviation identified by the “calibration”. The term “adjust a value toward a voltage value of interest” encompasses a concept of adjusting and making a value approach the voltage value of interest, a concept of making a value approach and become equal to the voltage value of interest, and a concept of matching a value to the voltage value of interest. In the following embodiments, a “voltage value” may be either a voltage indicated in analog or a digital voltage value (voltage data).

The output device 1 can measure a highly accurate value because it has been calibrated and adjusted by a primary standard or by a secondary standard traceable to the the primary standard, and the like. The output device 1 can measure a highly accurate voltage by, for example, being adjusted in terms of the measurable voltage by the primary standard.

The output device 1 outputs a signal serving as an adjustment reference to the outside, whereby equipment (e.g., the target equipment 200 to be described in the following embodiment) can be provided with a signal for adjusting the equipment. For example, the output device 1 can provide a voltage for adjusting the target equipment 200, by outputting a signal of a DC voltage of 1 mV serving as a reference.

In particular, the output device 1 according to the following embodiments is intended to improve the accuracy by identifying an error caused by a factor inherent in equipment and adjusting the interior. Specifically, the output device 1 uses a positive voltage value and a negative voltage value to suppress the influence of thermoelectromotive force generated in an internal circuit, thereby enabling further improvement of the accuracy. The processing device 100 is incorporated in the output device 1 that outputs, by using a DA converter 16, a predetermined voltage value serving as a reference. In the following embodiments, the configurations of the output device 1 and the processing device 100 that realize the foregoing will be described.

### First Embodiment

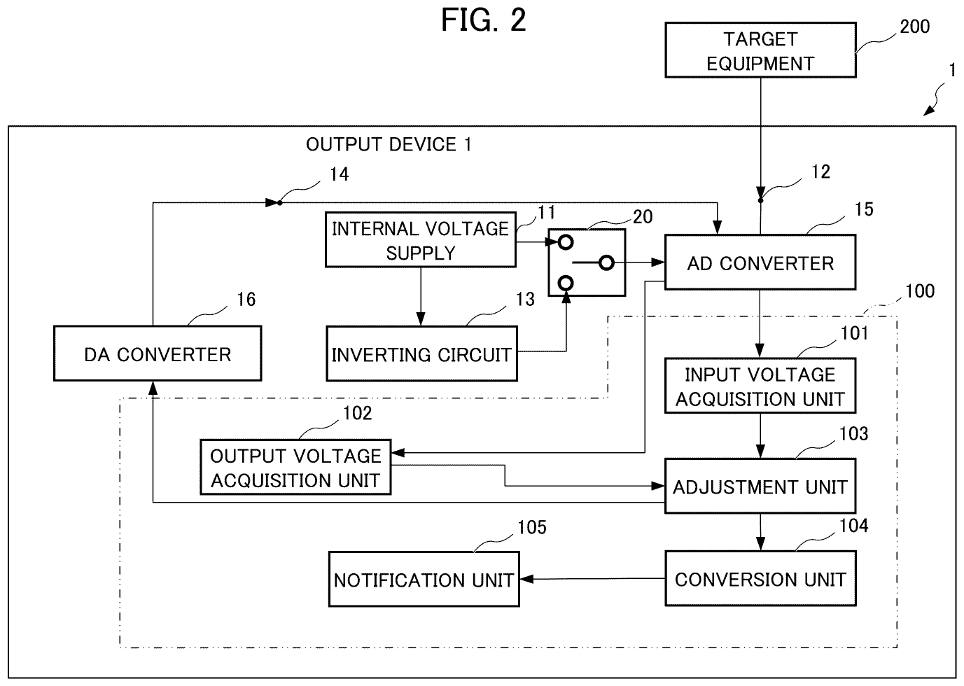

Next, an output device 1 and a processing device 100 according to a first embodiment of the present invention will be described with reference to FIGS. 1 and 2. The output device 1 according to the present embodiment outputs a voltage value to be adjusted to target equipment 200 to be adjusted, by using an internal voltage supply 11 provided in the output device 1. The output device 1 includes the processing device 100, the internal voltage supply 11, an input terminal 12, an inverting circuit 13, an output terminal 14, an AD converter 15, and a DA converter 16.

The processing device 100 is, for example, a processor such as a CPU or the like. The configuration of the processing device 100 will be described later.

The internal voltage supply 11 outputs a predetermined voltage value. For example, the internal voltage supply 11 is a reference voltage IC or the like that experiences a small change over time and has a small temperature coefficient.

The inverting circuit 13 inverts the voltage value outputted from the internal voltage supply 11. For example, as illustrated in FIG. 2, the inverting circuit 13 is connected to a switching circuit 20 that is capable of switching between the output from the internal voltage supply 11 and the output from the inverting circuit 13.

The input terminal 12 is used to receive an input of a voltage value from the outside. For example, the input terminal 12 is used as a connection terminal for connection to external equipment.

The output terminal 14 is used to output a voltage value to the outside. For example, the output terminal 14 is used as an output terminal for outputting a predetermined voltage value to external equipment.

The AD converter 15 converts a voltage value inputted thereto into a digital value and outputs the digital value. For example, the AD converter 15 performs AD conversion on a value inputted via a connection terminal or a value outputted from the DA converter 16, which will be described later.

The DA converter 16 outputs a predetermined voltage value to the output terminal 14. For example, the DA converter 16 outputs the predetermined voltage value to the output terminal 14. The DA converter 16 outputs the predetermined voltage value based on, for example, a setting value outputted from the processing device 100, which will be described later.

Next, the processing device 100 will be described. As illustrated in FIG. 2, the processing device 100 includes an input voltage acquisition unit 101, an output voltage acquisition unit 102, an adjustment unit 103, a conversion unit 104, and a notification unit 105.

The input voltage acquisition unit 101 is implemented by, for example, operation of a CPU. The input voltage acquisition unit 101 acquires a positive reference voltage value and a negative reference voltage value outputted as internal reference voltage values from the internal voltage supply 11 provided in the output device 1, and acquires a positive voltage value of interest and a negative voltage value of interest that are outputted from the target equipment 200 to be adjusted and are assumed to be equal to the internal reference voltage values. For example, the input voltage acquisition unit 101 acquires voltage values converted by the AD converter 15. For example, the input voltage acquisition unit 101 acquires a positive reference voltage value directly outputted from the internal voltage supply 11 and a negative reference voltage value outputted from the inverting circuit 13. For example, the input voltage acquisition unit 101 acquires a positive voltage value of interest and a negative voltage value of interest from adjustment target equipment connected to the input terminal 12.

The output voltage acquisition unit 102 is implemented by, for example, operation of the CPU. The output voltage acquisition unit 102 acquires a positive output voltage value and a negative output voltage value outputted from the DA converter 16. For example, the output voltage acquisition unit 102 acquires, via the AD converter 15, the output of the DA converter 16 connected to the output terminal 14.

The adjustment unit 103 is implemented by, for example, operation of the CPU. The adjustment unit 103 adjusts the positive output voltage value and the negative output voltage value toward the acquired positive reference voltage value and the acquired negative reference voltage value by adjusting a setting value of the DA converter 16. The adjustment unit 103 adjusts the positive output voltage value and the negative output voltage value toward the acquired positive voltage value of interest and the acquired negative voltage value of interest by adjusting a setting value of the DA converter 16. For example, the adjustment unit 103 adjusts a DAC value of the DA converter 16 to thereby adjust the positive output voltage value and the negative output voltage value toward the positive reference voltage value and the negative reference voltage value. Here, the adjustment unit 103 adjusts (matches) an output value (voltage value) that has been outputted from the DA converter 16 and converted by the AD converter 15 to a value resulting from conversion of an output value (voltage value) of the internal voltage supply 11 by the AD converter 15. In this way, it is possible to cancel, at the time of the adjustment, the characteristics of the AD converter 15 in which the AD conversion characteristics tend to change due to an ambient temperature or a change over time. Thus, the accuracy of the adjustment can be improved in comparison with a case where a digital value resulting from conversion by the AD converter 15 (e.g., a digital value of the voltage value of the internal voltage supply 11) is used as it is for the adjustment of the DA converter 16. By way of this adjustment, the adjustment unit 103 can match the voltage value outputted from the DA converter 16 to the reference voltage value.

For example, the adjustment unit 103 adjusts the positive output voltage value and the negative output voltage value toward the positive voltage value of interest and the negative voltage value of interest by adjusting the DAC value of the DA converter 16. Here, the adjustment unit 103 adjusts (matches) an output value (voltage value) that has been outputted from the DA converter 16 and converted by the AD converter 15 to a value resulting from conversion of an output value (voltage value) of the target equipment 200 by the AD converter 15. This makes it possible to cancel, at the time of the adjustment, the characteristics of the AD converter 15 in which the AD conversion characteristics tend to change due to an ambient temperature or a change over time. Thus, the accuracy of the adjustment can be improved in comparison with a case where a digital value resulting from conversion by the AD converter 15 (e.g., a digital value of the voltage value of the target equipment 200) is used as it is for the adjustment of the DA converter 16. This adjustment allows the adjustment unit 103 to obtain a deviation of the voltage value of interest from the reference voltage value as the adjustment result.

The conversion unit 104 is implemented by, for example, operation of the CPU. The conversion unit 104 converts the adjustment result to a measurement value of the voltage value of interest outputted from the target equipment. For example, the conversion unit 104 calculates the measurement value by using the adjustment result, as follows:

$$Measured value = Voltage value of internal power supply \times ( Positive voltage value of interest - Negative voltage value of interest ) / ( Positive reference voltage value - Negative reference voltage value )$$

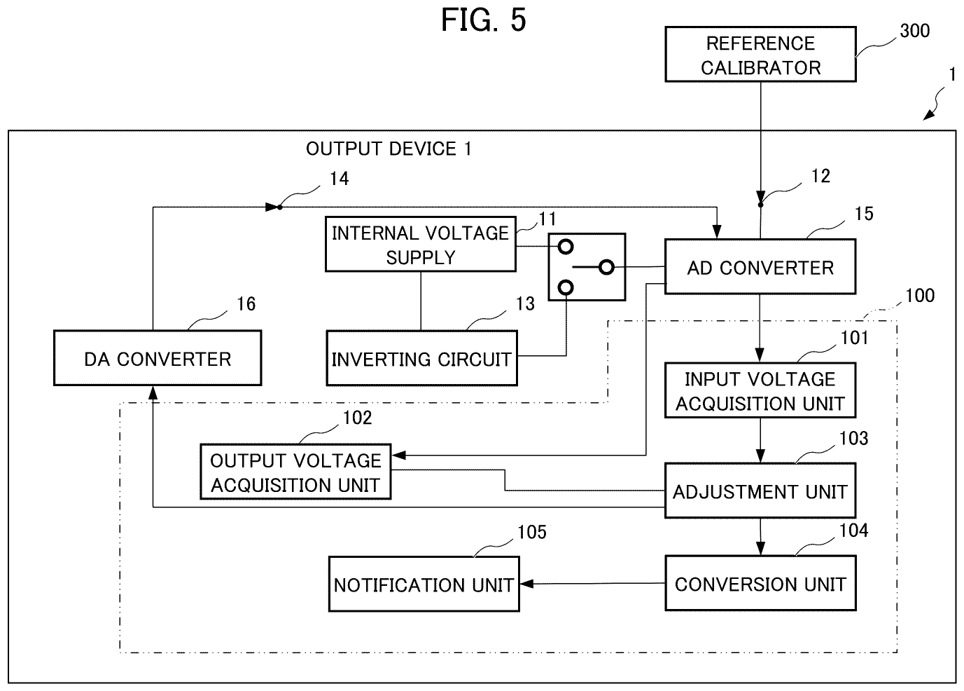

In this way, the conversion unit 104 calculates the voltage value (voltage value of interest) currently outputted from the target equipment 200 with respect to the accurate reference voltage value. In other words, the conversion unit 104 calculates the voltage value outputted from the target equipment 200, while using the reference voltage value as a reference. The voltage value of the internal voltage supply 11 is, for example, a “voltage value of the internal power supply” obtained in advance by way of connection to a reference calibrator 300 (see FIG. 5).

The conversion unit 104 converts the adjustment result to a calibration value for the voltage values of interest outputted from the target equipment. For example, the conversion unit 104 calculates the calibration value by using the adjustment result, as follows:

$$Calibration value = Predetermined voltage value \times Voltage value of internal power supply / ( ( Positive reference voltage value - Negative reference voltage value ) / 2 )$$

In this way, the conversion unit 104 converts the voltage value (voltage value of interest) currently outputted from the target equipment 200 to a voltage value (e.g., the positive output voltage value of the DA converter) to be calibrated, with respect to an accurate reference voltage value. That is, the conversion unit calculates a voltage value that should be set for the target equipment 200 to output an accurate positive voltage value of interest. Using (Positive reference voltage value-Negative reference voltage value) for the calculation makes it possible to cancel out the thermoelectromotive force of the internal power supply and the thermal resistance of wiring. Furthermore, calculating (Positive voltage value of interest-Negative voltage value of interest) makes it possible to cancel out the thermal resistance of wiring connected to the target equipment 200.

The notification unit 105 is implemented by, for example, operation of the CPU. The notification unit 105 notifies, to the outside, an adjustment result of the adjustment of the acquired positive output voltage value and the acquired negative output voltage value toward the acquired positive reference voltage value and the acquired negative reference voltage value. For example, the notification unit 105 notifies either one of the measurement value and the calibration value, which have been resulted from the conversion by the conversion unit 104, as the adjustment result. For example, the notification unit 105 outputs the measurement value or the calibration value to a display device such as a display or the like.

Next, an operation performed by the output device 1 and the processing device 100 will be described. First, the target equipment 200 is connected to the input terminal 12.

Next, the AD converter 15 performs AD conversion on a positive reference voltage value and a negative reference voltage value outputted from the internal voltage supply 11. Next, the input voltage acquisition unit 101 acquires the positive reference voltage value and the negative reference voltage value that have been subjected to the AD conversion. Next, the output voltage acquisition unit 102 acquires, via the AD converter 15, a positive output voltage value and a negative output voltage value outputted from the DA converter 16. Next, the adjustment unit 103 adjusts the positive output voltage value and the negative output voltage value toward the positive reference voltage value and the negative reference voltage value by adjusting the DA converter 16. In this way, the adjustment unit 103 makes the positive output voltage value and the negative output voltage value, which are outputted from the DA converter 16, approach the positive reference voltage value and the negative reference voltage value, respectively.

Next, the AD converter 15 performs AD conversion on a positive voltage value of interest and a negative voltage value of interest outputted from the target equipment 200. Next, the input voltage acquisition unit 101 acquires the positive voltage value of interest and the negative voltage value of interest that have been subjected to the AD conversion. Next, the output voltage acquisition unit 102 acquires, via the AD converter 15, a positive output voltage value and a negative output voltage value outputted from the DA converter 16. Next, the adjustment unit 103 adjusts the positive output voltage value and the negative output voltage value toward the positive voltage value of interest and the negative voltage value of interest by adjusting the DA converter 16. In this way, the adjustment unit 103 obtains, as an adjustment result, a deviation of the positive output voltage value and the negative output voltage value with respect to the positive reference voltage value and the negative reference voltage value.

Next, the conversion unit 104 calculates, from the adjustment result, a calibration value or a measurement value for the voltage values of interest that are outputted from the target equipment 200. Next, the notification unit 105 outputs the calculated calibration value or measurement value.

Next, a program according to the present embodiment will be described. Each of the components included in the processing device 100 can be implemented by hardware, software, or a combination thereof. Here, the implementation by software means that a computer reads and executes a program for the implementation.

The program can be stored in various types of non-transitory computer readable media and can be provided to a computer. The non-transitory computer readable media include various types of tangible storage media. Examples of the non-transitory computer readable media include a magnetic recording medium (e.g., a flexible disk, a magnetic tape, a hard disk drive), a magnetic-optical recording medium (e.g., a magnetic optical disk), a read only memory (CD-ROM), a CD-R, a CD-R/W, and a semiconductor memory (e.g., a mask ROM, a programmable ROM (PROM), an erasable PROM (EPROM), a flash ROM, and a random access memory (RAM)). A display program may be provided to the computer by way of various types of transitory computer readable media. Examples of the transitory computer readable media include an electrical signal, an optical signal, and an electromagnetic wave. The transitory computer readable medium can provide a program to the computer through a wired communication line, such as a wire and an optical fiber, or through a wireless communication.

The output device 1 and the processing device 100 according to the first embodiment described above exert the following effects.
(1) The processing device 100 incorporatable in the output device 1 that outputs, by using the DA converter 16, a predetermined voltage value serving as a reference. The processing device 100 includes: the input voltage acquisition unit 101 configured to acquire a positive reference voltage value and a negative reference voltage value outputted as internal reference voltage values from the internal voltage supply 11 that is provided in the output device 1 and acquire a positive voltage value of interest and a negative voltage value of interest that are outputted from the target equipment 200 to be adjusted and are assumed to be equal to the internal reference voltage values; the output voltage acquisition unit 102 configured to acquire a positive output voltage value and a negative output voltage value outputted from the DA converter 16; the adjustment unit 103 configured to adjust the acquired positive output voltage value and the acquired negative output voltage value toward the acquired positive reference voltage value and the acquired negative reference voltage value by adjusting a setting value of the DA converter 16, and adjust the acquired positive output voltage value and the acquired negative output voltage value toward the acquired positive voltage value of interest and the acquired negative voltage value of interest by adjusting a setting value of the DA converter 16; and the notification unit 105 configured to notify an adjustment result to the outside. The adjustment using the positive and negative voltages makes it possible to suppress the influence of thermoelectromotive force on the voltage values of interest and the reference voltage values. Therefore, the accuracy can be improved by adjusting an error inherent in the device.
(2) The output device includes: the above-described processing device 100; the internal power supply 11; the inverting circuit 13 that inverts the positive and negative of the internal voltage supply 11; the input terminal 12 that is used to receive an input of a voltage value from the outside; the output terminal 14 that is used to output a voltage value to the outside; and the DA converter 16 that outputs a predetermined voltage value to the output terminal 14 and has a DAC value adjustable based on adjustment by the adjustment unit 103. In general, the AD conversion characteristics of the AD converter 15 tend to change due to an ambient temperature or a change over time. Therefore, in a case where a conversion result of the AD converter 15 is used as it is as a reference for operation, errors are likely to occur in the resulting output voltage and a read voltage measurement value. In contrast, in the processing device 100, since the adjustment unit 103 simply compares the voltages of the two components, the capability as a comparator is maintained even when the AD conversion characteristics have changed. As a result, the accuracy of the output device 1 can be improved by adjusting the error inherent in the equipment.
(3) The processing device 100 further includes the conversion unit 104 configured to perform conversion of the adjustment result to a measurement value of the voltage values of interest that are outputted from the target equipment 200. The notification unit 105 notifies the measurement value resulting from the conversion. The processing device 100 further includes the conversion unit 104 configured to perform conversion of the adjustment result to a calibration value for calibrating the voltage values of interest that are outputted from the target equipment 200. The notification unit 105 notifies the calibration value resulting from the conversion. This feature makes it easy to check the measurement value and the calibration value.

### Second Embodiment

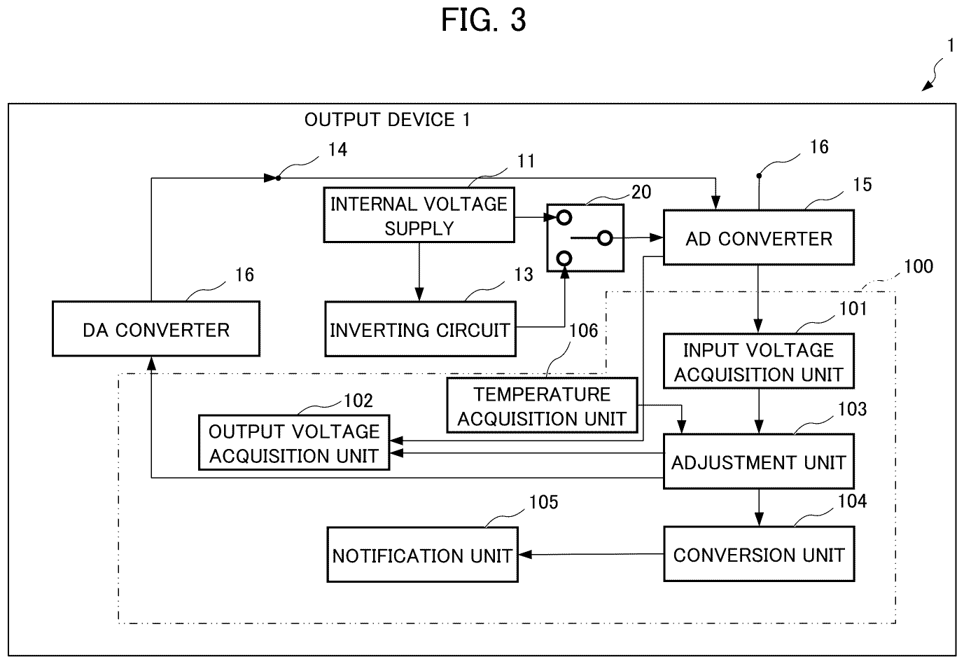

Next, an output device 1 and a processing device 100 according to a second embodiment of the present invention will be described with reference to FIG. 3. In the description of the second embodiment, the same components as those of the above-described embodiment are denoted by the same reference numerals, and the description thereof will be omitted or simplified. The output device 1 and the processing device 100 according to the second embodiment are different from those of the first embodiment in that in the second embodiment, output values outputted by an internal voltage supply 11 belonging to the output device 1 itself are subjected to adjustment.

The output device 1 and the processing device 100 according to the second embodiment are different from those of the first embodiment in that the second embodiment further includes a temperature acquisition unit 106. The output device 1 and the processing device 100 according to the second embodiment are different from those of the first embodiment in that an adjustment unit 103 adjusts a setting value of a DA converter 16 based on a positive reference voltage value, a negative reference voltage value, and an acquired temperature.

The temperature acquisition unit 106 is implemented by, for example, operation of a CPU. The temperature acquisition unit 106 acquires a temperature of the DA converter 16.

The adjustment unit 103 adjusts the setting value of the DA converter 16 such that the positive reference voltage value and the negative reference voltage value approach a positive output voltage value and a negative output voltage value, respectively. The adjustment unit 103 further adjusts the setting value of the DA converter 16 by using the acquired temperature. For example, the adjustment unit 103 adjusts the setting value of the DA converter 16 such that the following equation is satisfied. Positive output voltage value=Predetermined voltage value/Positive reference voltage value×(Positive reference voltage value-Negative reference voltage value)/2+temperature correction term

The temperature correction term is a function having a temperature as a variable. For example, the temperature correction term may be a linear expression having a temperature as a variable.

Next, an operation performed by the output device 1 and the processing device 100 will be described. First, the DA converter 16 performs DA conversion on a positive reference voltage and a negative reference voltage of the internal voltage supply 11. Next, the temperature acquisition unit 106 acquires a temperature. Next, the adjustment unit 103 adjusts a setting value of the DA converter 16 such that the positive reference voltage and the negative reference voltage are adjusted toward a positive output voltage and a negative output voltage. Next, an output voltage acquisition unit 102 acquires a positive output voltage and a negative output voltage. Next, the adjustment unit 103 determines the temperature correction term based on a temperature change, and adjusts the setting value of the DA converter 16.

The output device 1 and the processing device 100 according to the second embodiment described above exert the following effects.
(3) The processing device 100 further includes the temperature acquisition unit 106 configured to acquire a temperature of the DA converter 16, and the adjustment unit 103 adjusts a setting value of the DA converter 16 based on the positive reference voltage value, the negative reference voltage value, and the acquired temperature. Since the configuration of the DA converter 16 is less complicated than that of the AD converter 15, the DA converter 16 experiences a small temperature change and a small change over time. In a case where even a characteristic change caused by a slight temperature change should not be ignored, it is necessary to grasp the influence of such a temperature change in advance, measure an actual ambient temperature, and compensate a characteristic change caused by a temperature change, for a further improved accuracy.

### Third Embodiment

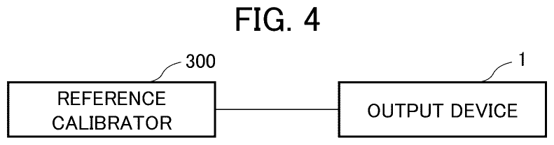

Next, an output device 1 and a processing device 100 according to a third embodiment of the present invention will be described with reference to FIGS. 4 and 5. In the description of the third embodiment, the same components as those of the above-described embodiments are denoted by the same reference numerals, and the description thereof will be omitted or simplified. The output device 1 and the processing device 100 according to the third embodiment are different from those of the first and second embodiments in that according to the third embodiment, an initial setting is made in advance according to an individual difference of an internal voltage supply 11 of each output device 1.

The output device 1 and the processing device 100 according to the third embodiment are different from those of the first and second embodiments in that an input voltage acquisition unit 101 of the third embodiment acquires reference calibration voltage values for calibrating internal reference voltage values. The output device 1 and the processing device 100 according to the third embodiment are different from those of the first and second embodiments in that an adjustment unit 103 of the third embodiment adjusts a positive output voltage value and a negative output voltage value toward the reference calibration voltage values by adjusting a setting value of a DA converter 16.

Next, an operation performed by the output device 1 and the processing device 100 will be described. First, an input terminal 12 is connected to an output of a reference calibrator 300 that outputs reference calibration voltage values, and then an AD converter 15 performs AD conversion on the reference calibration voltage values. Next, the adjustment unit 103 adjusts a setting value of the DA converter 16 such that a positive output voltage value and a negative output voltage value are adjusted toward a positive reference calibration voltage and a negative reference calibration voltage as the reference calibration voltages. Next, an output voltage acquisition unit 102 acquires a positive output voltage value and a negative output voltage value.

Next, the AD converter 15 performs AD conversion on a positive reference voltage value and a negative reference voltage value. The adjustment unit 103 adjusts a setting value of the DA converter 16 such that the positive reference voltage value and the negative reference voltage value are adjusted toward the adjusted positive output voltage value and the adjusted negative output voltage value. Based on the two setting values of the DA converter 16, which have been obtained through the matching operation, the absolute value of the internal reference voltage values can be accurately grasped. Once the reference voltage values are grasped, a highly accurate voltage can be outputted using the reference voltage values, and the voltage of target equipment can be measured with high accuracy.

The output device 1 and the processing device 100 according to the third embodiment described above exert the following effects.
(4) The input voltage acquisition unit 101 acquires reference calibration voltage values for calibrating internal reference voltage values, and the adjustment unit 103 adjusts a positive output voltage value and a negative output voltage value toward the reference calibration voltage values by adjusting a setting value of the DA converter 16. By virtue of this feature, the setting value of the DA converter 16 can be set in advance in accordance with the voltage value of the internal voltage supply 11 having a large “individual difference between devices” or “variation depending on individuals”, so that the accuracy of the output device 1 can be improved.

It should be noted that the present invention is not limited to the above-described preferred embodiments of the output device and the processing device of the present invention, and modifications can be made as appropriate. For example, in the above-described embodiments, the output device 1 includes the output terminal 14 and the input terminal 12, but the present invention is not limited thereto. The output device 1 does not have to include the output terminal 14 and the input terminal 12.

In the above-described embodiments, the processing device 100 may include a log storage unit that stores a log of the adjustment. This feature makes it possible to use a history of the adjustment by the processing device 100 for analyzing the output device 1.

In each of the above-described embodiments, the processing device 100 may transmit to an external server (not shown) a log of temperatures inside and outside the output device 1 and a log of the adjustment. It is also possible to adopt a system in which an external server performs statistical analysis of information acquired from a plurality of the output devices 1. This feature allows the external server to identify an output device 1 in which an abnormality has occurred, and perform wireless calibration and adjustment without physical electric connection to a primary standard or the like.

For example, the output device may include the above-described processing device, an internal voltage supply, an inverting circuit that inverts the positive and negative of the internal voltage supply, a communication unit that inputs a voltage value from the outside and outputs a voltage value to the outside via wireless communication, and a DA converter that outputs a predetermined voltage value to the output terminal and is adjustable with an adjustment value determined based on adjustment by the adjustment unit.

In the above embodiments, the voltage value of a direct current has been described, but the voltage value may be of an alternating current. For example, an AC voltage value may be outputted from the DA converter by causing the adjustment unit to periodically change the adjustment of the DA converter over time.

In the above-described embodiments, the notification unit 105 notifies the measurement value or the calibration value to the outside, but the present invention is not limited thereto. The notification unit 105 may notify both the measurement value and the calibration value to the outside.

In the above-described embodiments, the adjustment unit 103 may change the adjustment result based on a voltage value preset as an output value of the DA converter 16. The adjustment unit 103 may change the adjustment result based on, for example, a multiplying factor for a predetermined voltage value to be outputted from the output terminal 14, with respect to a reference voltage value. For example, the adjustment unit 103 may receive an input of a multiplying factor from the outside and change the adjustment result based on the received multiplying factor.

In the above-described embodiments, the conversion unit 104 may operate as a part of the adjustment unit 103. At the time of the adjustment, the adjustment unit 103 may adjust the DA converter 16 using a value converted by the conversion unit 104.

In the above-described embodiment, the processing device 100 acquires the positive voltage value of interest and the negative voltage value of interest from the target equipment 200, but the present invention is not limited thereto. For example, the processing device 100 may output a DAC value (adjustment value) of the DA converter 16 for adjustment toward the positive and negative internal reference voltage values acquired from the internal voltage supply 11, without acquiring the positive voltage value of interest or the negative voltage value of interest from the target equipment 200. In other words, the processing device 100 may control the DA converter 16 such that voltage values approximate to the reference voltage values of the internal voltage supply 11 are outputted. In this case, the adjustment unit 103 adjusts the setting value of the DA converter 16 and adjusts a positive output voltage value and a negative output voltage value toward the acquired positive reference voltage value and the acquired negative reference voltage value. This feature makes it possible to perform control to output a highly accurate voltage value without having to acquire a positive voltage value of interest or a negative voltage value of interest from the target equipment 200.

### EXPLANATION OF REFERENCE NUMERALS

1: Output device
11: Internal voltage supply
16: DA converter
100: Processing device
101: Input voltage acquisition unit
102: Output voltage acquisition unit
103: Adjustment unit
104: Conversion unit
105: Notification unit
106: Temperature acquisition unit

1. A processing device incorporatable in an output device that outputs, by using a DA converter, a predetermined voltage value serving as a reference, the processing device comprising:
an input voltage acquisition unit configured to acquire a positive reference voltage value and a negative reference voltage value outputted as internal reference voltage values from an internal voltage supply that is provided in the output device;
an output voltage acquisition unit configured to acquire a positive output voltage value and a negative output voltage value outputted from the DA converter; and
an adjustment unit configured to adjust a setting value of the DA converter and adjust the positive output voltage value and the negative output voltage value toward the positive reference voltage value acquired and the negative reference voltage value acquired.

2. The processing device according to claim 1, further comprising:
a notification unit configured to notify an adjustment result of adjustment by the adjustment unit to an outside, wherein
the input voltage acquisition unit acquires a positive voltage value of interest and a negative voltage value of interest that are outputted from target equipment to be adjusted and are assumed to be equal to the internal reference voltage values, and
the adjustment unit adjusts the positive output voltage value and the negative output voltage value toward the positive voltage value of interest acquired and the negative voltage value of interest acquired.

3. The processing device according to claim 2, further comprising:
a conversion unit configured to perform conversion of an adjustment result to a measurement value of a voltage value of interest outputted from the target equipment, wherein
the notification unit notifies the measurement value resulting from the conversion as an adjustment result.

4. The processing device according to claim 2, further comprising:
a conversion unit configured to perform conversion of an adjustment result to a calibration value for calibrating a voltage value of interest outputted from the target equipment, wherein
the notification unit notifies the calibration value resulting from the conversion as an adjustment result.

5. The processing device according to claim 1, further comprising:
a temperature acquisition unit configured to acquire a temperature of an ambient atmosphere, wherein
the adjustment unit adjusts a setting value of the DA converter based on the positive reference voltage value, the negative reference voltage value, and the temperature acquired.

6. The processing device according to claim 1, wherein
the input voltage acquisition unit acquires a reference calibration voltage value for calibrating the internal reference voltage values, the reference calibration voltage value being provided from an outside of the output device, and
the adjustment unit adjusts the positive output voltage value and the negative output voltage value toward the reference calibration voltage value by adjusting a setting value of the DA converter.

7. The processing device according to claim 1, wherein
the adjustment unit changes an adjustment result based on a voltage value preset as an output value of the DA converter.

8. An output device comprising:
the processing device according to claim 1;
the internal voltage supply;
an inverting circuit that inverts positive and negative of the internal voltage supply;
an input terminal that is used to receive an input of a voltage value from an outside;
an output terminal that is used to output a voltage value to the outside; and
a DA converter that outputs a predetermined voltage value to the output terminal and is adjustable with an adjustment value that is determined based on adjustment by the adjustment unit.

9. A non-transitory computer readable medium storing instructions for causing a computer to operate as a processing device incorporatable in an output device that outputs, by using a DA converter, a predetermined voltage value serving as a reference, the program causing the computer to function as units comprising:
an input voltage acquisition unit configured to acquire a positive reference voltage value and a negative reference voltage value outputted as internal reference voltage values from an internal voltage supply that is provided in the output device;
an output voltage acquisition unit configured to acquire a positive output voltage value and a negative output voltage value outputted from the DA converter; and
an adjustment unit configured to adjust a setting value of the DA converter and adjust the positive output voltage value and the negative output voltage value toward the positive reference voltage value acquired and the negative reference voltage value acquired.
